(19) United States
(12) Patent Application Publication
(10) Pub. No.: US 2019/0392300 A1
(43) Pub. Date: Dec. 26, 2019

(54) SYSTEMS AND METHODS FOR DATA COMPRESSION IN NEURAL NETWORKS

(71) Applicant: NEC Laboratories Europe GmbH, Heidelberg (DE)

(72) Inventors: Nicolas Weber, Dossenheim (DE); Felipe Huici, Dossenheim (DE); Mathias Niepert, Heidelberg (DE)

(21) Appl. No.: 16/012,832

(22) Filed: Jun. 20, 2018

(51) Int. Cl. G06N 3/08; H03M 7/30; G06N 3/04

(52) U.S. Cl. CPC G06N 3/08; G06N 3/04; H03M 7/3059

(57) ABSTRACT

A method for processing a neural network includes performing a decompression step before executing operations associated with a block of layers of the neural network, performing a compression step after executing operations associated with the block of layers of a neural network, gathering performance indicators for the executing the operations associated with the block of layers of the neural network, and determining whether target performance metrics have been met with a compression format used for at least one of the decompression step and the compression step.

### FIELD

The present invention relates generally to neural networks, and more particularly to systems and methods for training and processing neural networks.

### BACKGROUND

Neural networks consist of a series of interconnected nodes (often arranged in layers) that each perform an operation. Such neural network operations are typically very data intensive. Therefore, processors with high memory bandwidths are often used to execute such neural network operations. Current state-of-the-art neural networks pass raw data from one layer to another. Because the amount of raw data passed from one layer of a neural network to the next is often too large to be stored at a processor cache, large amounts of data must be transferred between a main memory and a processor, e.g. a CPU or GPU, responsible for executing the neural network operations. Such data transfer requirements impose a number of limitations on neural network performance. First, as many neural network layers are memory bound, their performance is limited by the speed with which huge amounts of data can be retrieved from a main memory. Second, the cache of accelerators (e.g. GPUs), which is usually quite small in comparison to a main memory, is a limiting factor. Third, current state-of-the-art methods and systems for processing neural networks use 16-bit half-precision floating point (or even 8-bit integer) number format in order to reduce the amount of data that must be retrieved from memory as it halves the amount of data that must be retrieved when 32-bit single-precision floating point number format is used. As a result, however, all operations must be performed with 16-bit half-precision floating point (or 8-bit integer) numbers—which can negatively impact the accuracy of neural network modeling operations (in addition, on processing units without a dedicated 16-bit half-precision floating point arithmetic-logic unit, required format conversions negatively impact the performance of the operations). Fourth, current state-of-the-art research further concentrates on reducing the amount of data required for parameters of the neural network but ignores the performance constraints that result from storing the huge amounts of input/output data for each layer of the neural network at a main memory.

### SUMMARY

According to an embodiment, a method for processing a neural network is provided. The method includes performing a decompression step before executing operations associated with a block of layers of the neural network, performing a compression step after executing operations associated with the block of layers of a neural network, gathering performance indicators for the executing the operations associated with the block of layers of the neural network, and determining whether target performance metrics have been met with a compression format used for at least one of the decompression step and the compression step.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1a depicts the execution of neural network operations using a state-of-the-art process;

FIG. 1b depicts the execution of neural network operations using a process according to an embodiment of the invention that involves data compression;

FIG. 1c depicts the execution of neural network operations using a process according to an embodiment of the invention in which compressed input data is decompressed before a first layer of a block of layers and in which the output data of the last layer in the block of layers is compressed before being stored;

FIG. 2a depicts the execution time required for a single layer of a neural network that does not utilize compression and the execution time required for a single layer of a neural network that does utilize compression;

FIG. 2b depicts the execution time required for two layers of a neural network that cannot be combined into a single meta-layer and the execution time required for two layers of a neural network that can be combined into a single meta-layer;

FIG. 3 illustrates a system for processing a neural network according to an embodiment of the invention;

FIG. 4 illustrates a process for training a neural network, wherein training the neural network includes determining compression formats for each layer of the neural network that satisfy processing performance targets and neural network accuracy targets;

FIG. 5 illustrates modeling of execution of neural network operations during the training of a neural network according to an embodiment of the invention; and

FIG. 6 illustrates a method for processing a neural network according to an embodiment of the invention.

### DETAILED DESCRIPTION

Embodiments of the present invention provide for compressing the input and output data of neural network layers during the execution of neural network operations. One or more embodiments of the present invention provide methods and systems for processing neural networks in which input data for a block of layers of the neural network that has previously been compressed is decompressed before execution of the operations associated with the respective block of layers and in which the output data of the respective block of layers is compressed prior to being stored. Furthermore, one or more embodiments of the present invention provide methods and systems for automated and adaptive selection of compression schemes (e.g., lossless or lossy compression types) and compression parameters (e.g., that determine a level of compression) to use for the output of individual neural network layers and meta-layers in order to achieve certain performance metrics, e.g. a given model accuracy target, a target memory usage, or a target computation time.

As a result, embodiments of the present invention can provide a number of advantages for executing neural network operations as compared to the state-of-the-art. First, embodiments of the invention can reduce the amount of data required to be stored in memory during the execution of neural network operations and can therefore reduce the amount of data that must to be read and/or written from the main memory during the execution of the neural network operations. Therefore, one or more embodiments of the present invention can execute neural network operations while requiring less memory bandwidth and consuming less memory resources as compared to state-of-the-art processes for executing neural network operations. In addition, by providing an automated and adaptive selection system to choose a compression scheme and parameters, one or more embodiments of the present invention can provide for an adjustable level of accuracy of the neural network operations tailored to a specific application and to host-system compute and memory resource constraints. In this manner, embodiments of the invention can provide for superior performance during execution of neural network operations despite the additional compute resources required to perform compression and decompression. Furthermore, in comparison to state-of-the-art processes that utilize 16-bit half-precision floating point numbers or 8-bit integer numbers, one or more embodiments of the invention can work with 32-bit single precision floating point numbers inside the layers of the neural network and compress only the data that are stored in the main memory. If lossless compression is used, then one or more embodiments of the present invention can produce the same results as using uncompressed 32-bit single-precision floating point numbers, all the while requiring less memory storage and bandwidth. Therefore, one or more embodiments of the present invention can provide superior accuracy compared to state-of-the-art processes that utilize 16-bit half-precision floating point numbers or 8-bit integer numbers.

Furthermore, in setups where the neural network is a multi-node or multi-device system, e.g. a cluster, an accelerator cluster, an edge-computing system, or a multi-accelerator node, one or more embodiments of the invention can reduce the amount of data needed to be transferred between the nodes/devices. Clusters often use network interconnects with high bandwidth and low latency properties, e.g. InfiniBand. However, such network interconnects are still orders of magnitude slower than RAM. In clusters that use accelerators (e.g. GPUs), data can be transferred directly, over InfiniBand, from a first accelerator of one node to a second accelerator of another node, e.g. using NVIDIA's GPUDirect. As the data is directly accessed from the accelerator memory, it is normally not compressed. Devices at an “Edge,” e.g. a smartphone that offloads a computationally intensive portions of a computation to a server, are usually connected using wireless, low-bandwidth connections. In nodes with multiple accelerators, data is transferred between accelerators using PCIE or NVIDIA's NVLink. However, the bandwidth and latency of these bus systems is orders of magnitude slower than of RAM. Therefore, in all such setups, a reduction in the amount of data transferred between nodes/devices can provide significant performance enhancements.

According to an embodiment, a method is provided for processing a neural network. The method includes adding a decompression step before and a compression step after executing the operations associated with a block of layers of a neural network. The method further includes gathering information about a current computation time, memory usage, and model accuracy, and modifying a compression scheme used for the decompression step and the compression step and the parameters of the compression scheme in order to meet target values for accuracy, memory usage, and/or computation time. For example, if execution of the neural network is taking longer than desired, modifying the compression scheme can, for example, involve switching from lossless to lossy compression.

According to an embodiment, a system is provided for processing a neural network. The system includes a controller and a plurality of compute devices. The controller can be, e.g., a computer that includes compute resources, storage resources, and network resources. The compute resources include a compute scheduler and a compression optimizer, which can be, e.g., a processor, processor core, or processor component configured to execute processor executable instructions stored at the storage resources of the controller. The storage resources include a main memory. Each of the plurality of compute devices includes a processor, e.g. a central processor unit (CPU) or a graphics processor unit (GPU), a cache, e.g. a CPU cache or a GPU cache, and a main memory. In the case of a CPU or a GPU, each processor of each compute device can be a single instruction, multiple data (SIMD) unit in the CPU or GPU processor and each cache can be the self-organized on-chip cache shared between all such SIMD units or a portion thereof. In addition, the compute device can be a vector processor or a field programmable gate array (FPGA). Each of the compute devices, and specifically the processors thereof, monitor performance metrics, e.g. bandwidth and compute utilization, execution times, cache hit rates, and memory consumption, and report those performance metrics to the compression optimizer. The compression optimizer is configured to evaluate the performance metrics provided by the compute devices and determines a compression scheme and compression parameters to utilize during processing of the neural network. The compression optimizer is further configured to provide the determined compression scheme and compression parameters to the compute scheduler. The compute scheduler is configured to launch functions on the individual compute devices and to schedule such launches.

Embodiments of the present invention can evaluate both (i) performance metrics monitored and recorded during a prior training period of a neural network, and (ii) performance metrics monitored in real time during the processing of the neural network. Embodiments of the present invention can then utilize such performance metrics in order to determine a compression scheme and compression parameters to utilize during the processing of the neural network.

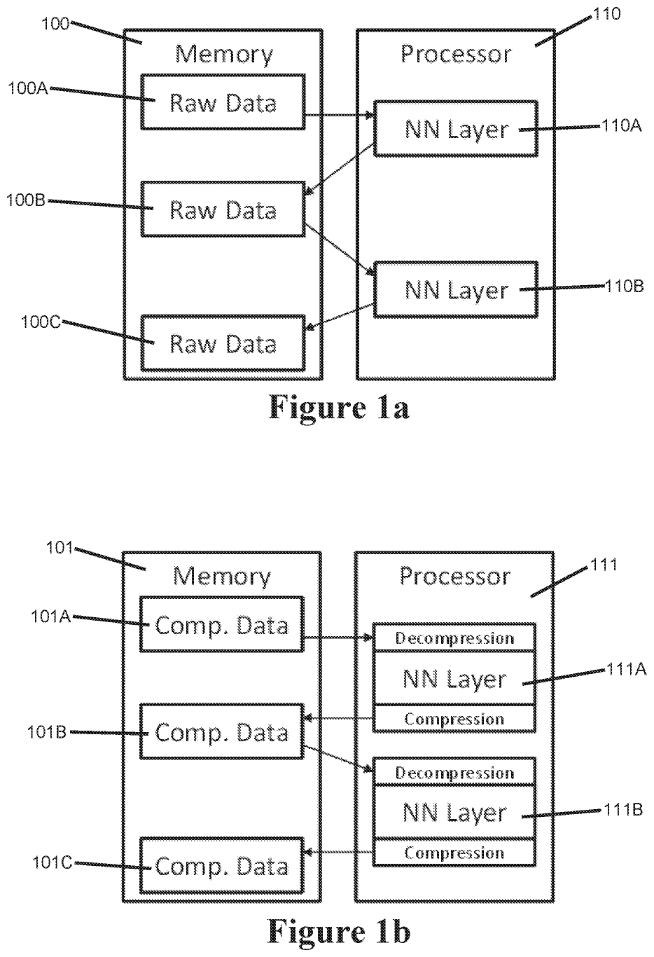

FIG. 1a depicts the execution of neural network operations using a state-of-the-art network with no data compression. In FIG. 1a, raw data 100A stored at main memory 100 is loaded into processor 110 as input into neural network layer 110A and the output of the neural network layer 110A is thereafter stored at the main memory 100 as raw data 100B. Raw data 100B is then loaded into processor 110 as input into neural network layer 110B and the output of the neural network layer 110B is thereafter stored at the main memory 100 as raw data 100C.

FIG. 1b depicts the execution of neural network operations using a process according to an embodiment of the invention that involves data compression. In FIG. 1b, compressed raw data 101A stored at main memory 101 is loaded into processor 111 where it is decompressed prior to being fed into neural network layer 111A as input. Furthermore, the output of the neural network layer 111A is thereafter compressed at the processor 111 prior to being stored at the main memory 101 as raw data 101B. Compressed raw data 101B is thereafter loaded into processor 111 where it is decompressed prior to being fed into neural network layer 111B as input. The output of the neural network layer 111B is then compressed at the processor 111 prior to being stored at the main memory 101 as raw data 101C.

Applying data decompression to the input and data compression to the output of every layer of a neural network can require a large number of computations and can reduce the performance benefits achieved by performing said data compression. However, by monitoring performance metrics, e.g. bandwidth and compute utilization, execution times, cache hit rates, and memory consumption, and determining a compression scheme and compression parameters to utilize during the compression and decompression operations that are based on the monitored performance metrics, neural networks can be processed with improved performance and accuracy. For example, during the processing of the neural network illustrated in FIG. 1b, both performance metrics monitored during a previous training period of the neural network and performance metrics monitored in real time during the processing of the neural network can be evaluated in order to determine a compression scheme and compression parameters for the compression of the output of neural network layer 111A and of the output of neural network layer 111B. In determining the compression scheme and compression parameters to be used during the processing of a neural network, different compression schemes and parameters can be utilized for the decompression of data that serves as input to a particular neural network layer and for the compression of the output of that particular neural network layer. For example, the compression of the output of neural network layer 111A and the decompression of the compressed raw data 101B could be performed according to a lossless compression scheme or with a low compression ratio, while the compression of the output of the neural network layer 111B could be performed according to a lossy compression scheme or with a high compression ratio.

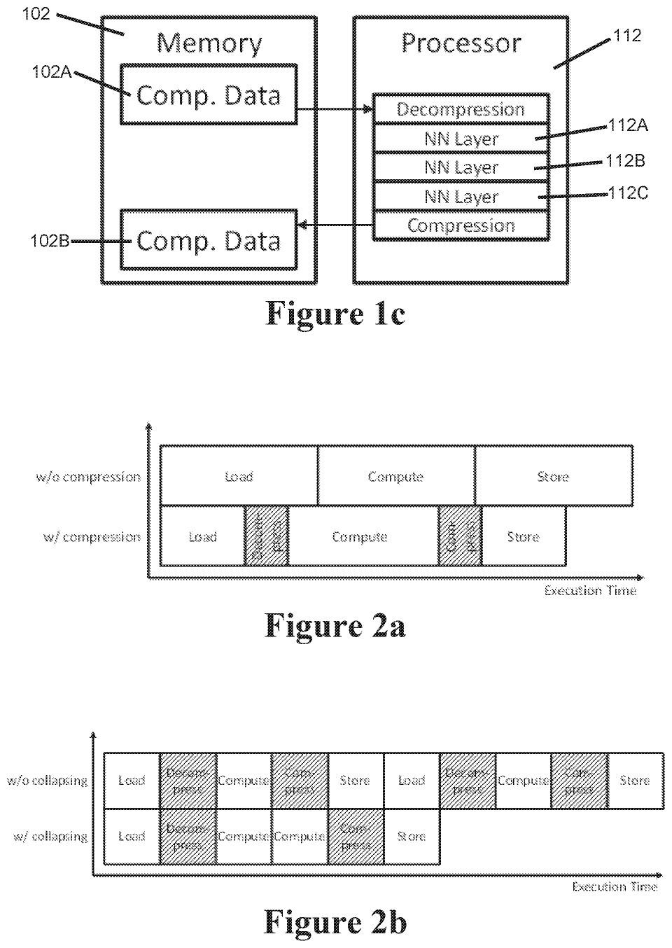

FIG. 2a illustrates the execution time required for a single layer of a neural network that does not utilize compression (e.g. the neural network of FIG. 1a) and the execution time required for a single layer of a neural network that does utilize compression (e.g. the neural network of FIG. 1b). As can be seen in FIG. 2a, the execution time required for a single layer of a neural network can be reduced with appropriate selection of compression and decompression schemes.

Furthermore, it is possible to reduce the negative impact on performance resulting from the data decompression and data compression operations by dividing input data for a first layer of a block of layers of a neural network up into a plurality of subsets and sequentially executing neural network operations on each subset such that the output (corresponding to a single input subset) of each layer of the block of layers can be stored in a cache (or caches) available to the processor (or processors) involved in executing the neural network operations. In such manner, the neural network operations associated with the block of layers can be executed without reading input data from or writing output data to a main memory before or after performing the operations associated with each intermediate layer of the block of layers. For example, U.S. patent application Ser. No. 15/889,275, which is incorporated by reference herein, describes such methods for neural network acceleration through depth-first processing.

FIG. 1c depicts the execution of neural network operations in which compressed input data is decompressed before a first layer of a block of layers and in which the output data of the last layer in the block of layers is compressed before being stored in a main memory. In FIG. 1c, compressed raw data 102A stored at main memory 102 is loaded into processor 112 where it is decompressed prior to being fed into neural network layer 112A as input. The output of the neural network layer 112A is fed directly into neural network layer 112B as input, and the output of neural network 112B is fed directly into neural network layer 112C as input. Thereafter, the output of neural network layer 112C is compressed at the processor 112 prior to being stored at the main memory 102 as raw data 102B. In this manner, neural network layers 112A, 112B, and 112C form a single meta-layer of the neural network.

FIG. 2b illustrates the execution time required for two layers of a neural network that cannot be combined into a single meta-layer (e.g. the neural network of FIG. 1b) and the execution time required for two layers of a neural network that can be combined into a single meta-layer (e.g. the neural network of FIG. 1c). As can be seen in FIG. 2b, the execution time required for additional decompression and compression processes can be eliminated when multiple layers of a neural network can be combined into a single meta-layer.

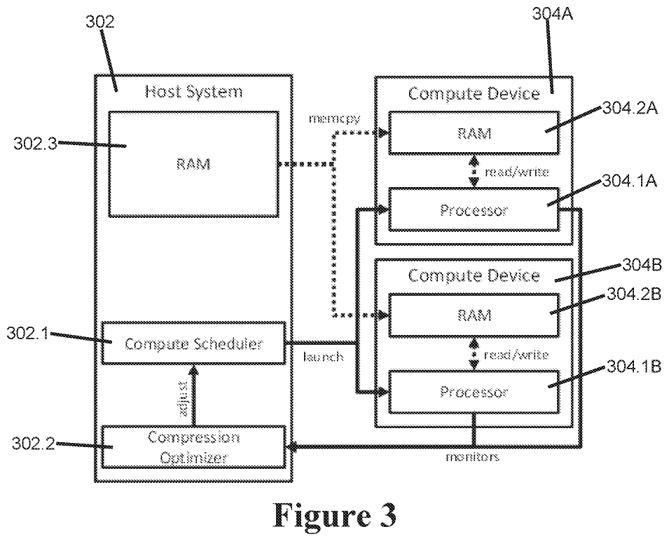

FIG. 3 shows a system for processing a neural network according to an embodiment of the invention. The system includes a host system 302, which serves as a controller, and a plurality of compute devices 304A and 304B. The host system 302 includes compute resources, storage resources, and network resources. The compute resources include a compute scheduler 302.1 and a compression optimizer 302.2, each of which is a processor configured to execute processor executable instructions stored at the storage resources of the controller. The storage resources include a main memory, i.e. random access memory (RAM) 302.3. Each of the plurality of compute devices 304A and 304B includes a processor (304.1A and 304.1B), a processor cache (304.2A and 304.2B), and a main memory (304.3A and 304.3B). The processors 304.1A and 304.1B can be, e.g. a CPU, a GPU, an SIMD unit of a CPU or GPU, a vector processor, or an FPGA. The caches 304.2A and 304.2B can be, e.g., a CPU cache, a GPU cache, a self-organized on-chip cache shared between all SIMD units of a CPU or GPU, etc. Each of the compute devices 304A and 304B, and specifically the processors 304.1A and 304.1B thereof, monitor performance metrics, e.g. memory bandwidth utilization, compute utilization, execution times, and cache hit rates, and report those performance metrics to the compression optimizer 302.2. The main memories 304.3A and 304.3B are off processor chip random access memories (RAM). In various embodiments, the caches 304.2A and 304.2B and/or the main memories 304.3A and 304.3B are the same memory common to multiple compute devices or a portion of memory common to multiple compute devices.

The compression optimizer 302.2 is configured to evaluate the performance metrics and to determine a compression scheme and compression parameters to utilize during processing of the neural network. The compression optimizer 302.2 is further configured to provide the determined compression scheme and compression parameters to the compute scheduler 302.1. The RAM 302.3 can store data pertaining to performance metrics monitored during previous training phases of the neural network as well as processor executable instructions to be executed by the compression optimizer 302.2 and the compute scheduler 302.1.

The compute scheduler 302.1 is configured to launch functions on the individual compute devices 304A and 304B and to schedule such launches. When the compute scheduler 302.1 launches a function at the individual compute devices 304A and 304B, the individual compute devices execute neural network operations. During the execution of individual neural network operations, the processors 304.1A and 304.1B load compressed data stored at the main memories 304.3A and 304.3B, decompress the data to provide input data for a neural network operation, execute a neural network operation so as to provide output data, compress the output data, and then write the compressed output data to the main memories 304.3A and 304.3B. Alternatively, if the neural network operations executed by the processors 304.1A and 304.1B are part of a neural network layer that can be combined with other neural network layers into a single meta-layer, the processors 304.1A and 304.1B may execute multiple neural network operations between the loading and decompression and the compression and storing.

During the execution of neural network operations, the processors 304.1A and 304.1B check to see if data is present in their respective caches 304.2A and 304.2B. If the data is not present in the caches 304.2A and 304.2B, the processors 304.1A and 304.1B access the main memories 304.3A and 304.3B—which can take multiple cycles. Meanwhile—and throughout the processing of the neural network—the processors report performance metrics to the compression optimizer 302.2. During periods where the processors 304.1A and 304.1B are accessing the main memories 304.3A and 304.3B, memory bandwidth utilization will be high but processor utilization will be relatively low. As many neural network layers are memory bound (Threshold, ReLU, most of the activation layers, . . . ), the compression optimizer 302.2. evaluates the performance metrics supplied by the processors 304.1A and 304.1B and selects compression schemes and compression parameters that appropriately utilize idle compute resources (to decompress and/or compress input and/or output, respectively) and simultaneously reduce pressure on the memory system in order to improve neural network processing performance.

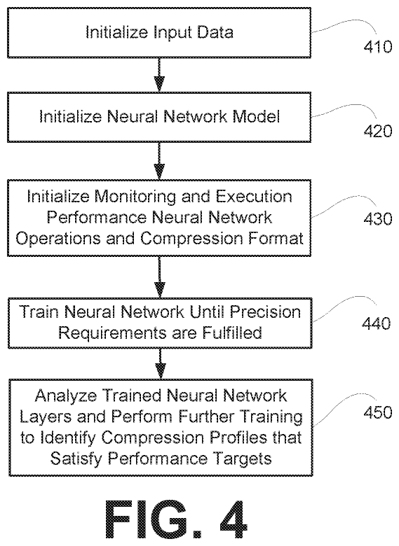

FIG. 4 illustrates a process for training a neural network, wherein training the neural network includes determining compression formats for each layer of the neural network that satisfy processing performance targets and neural network accuracy targets. At 410, the process initializes input data. The initialization of input data at 410 can be performed according to the following pseudo-code:

// init data
TrainingInput = TrainingSet.loadInputs( );
TrainingOutput = TrainingSet.loadOutputs();
TestingInput = TestingSet.loadInput( );
TestingOutput = TestingSet.loadOutputs( );

At 420, the process initializes the neural network model. The neural network model can be initialized according to the following pseudo-code:

| // init neural network model | |
|---|---|
| nnModel | = createNeuralNetworkModel( ); |

At 430, the process initializes the monitoring of the execution performance of neural network operations and initializes a compression format, i.e. a compression scheme and compression parameters. The initialization of the monitoring of the execution performance and the compression format can be performed according to the following pseudo-code:

// init monitoring
nnModel.initMonitoring( );
nnModel.setCompression(None, −inf, +inf);

At 440, the process performs training of the neural network until the network fulfills certain precision requirements. If the precision requirements are not met with the current gradients and/or weighting, the process updates the gradients and/or weights until the precision requirements are met. Training of the neural network can be performed according to the following pseudo-code:

```
// perform training
while(true):
  X = nnModel.predict(TrainingInput)
  if(calcError(X, TrainingOutput) < minError):
    break;
  Y = nnModel.calculateGradients(X);
  nnModel.updateModel(X, Y, TrainingInput, TrainingOutput);
```

At 450, the process analyzes each layer of the trained neural network, i.e. the neural network having the gradients and weights that were successful in satisfying the precision requirements for the neural network, and performs further training steps to identify one or more compression profiles that specify a compression format for each layer of the trained neural network. Training of neural networks is an iterative process, so the compression can be adjusted between different training epochs to further improve on the optimization targets. For example, the training could start with a lossless or even no compression and then gradually increase the compression between the epochs. The training of the neural network to identify compression profiles that meet certain performance targets can be performed according to the following pseudo-code:

```
// find compression profile
for(layer : nnModel.layers( )):
  ValueRange = layer.monitoredValueRange( );
  for(compression : {None, LossLess, LightLossy,
  MediumLossy, HighLossy}):
    for(ratio : {0.0 to 1.0}):
      layer.setCompression(compression, ValueRange.min,
      ValueRange.max);
      X = nnModel.predict(TestingInput);
      if(calcError(X, TestingOutput) >= minError):
        layer.setCompression(compression - 1,
        ValueRange.min, ValueRange.max);
        break;
```

During such training, present compression values are specified for each layer of the neural network, information about a current computation time, memory usage, and model accuracy is recorded (by the processors of the compute devices executing the neural network operations, e.g. processors 304.1A and 304.1B) and transmitted to a controller (e.g. the host device 302, and specifically, the compression optimizer 302.2), and the compression values for each layer of the neural network are modified until a compression profile that meets target values for accuracy, memory usage, and/or computation time is determined. Each of the one or more compression profiles simultaneously satisfy the precision requirements for the neural network and one or more performance metrics for processing of the neural network. Each of the compression profiles can be determined by establishing a particular set of optimization targets, e.g., best overall performance, least memory usage, accuracy requirements, etc., and iteratively adjusting the compression formats until a compression profile that satisfies each of the optimization targets in the set is identified.

Data compression schemes utilized by the processors that process the neural network should fulfill certain properties. Stream-based compression schemes are difficult to use due to the processors (CPU, GPU, . . . ) that process the neural network being arranged in parallel. Therefore, a block-based compression scheme (e.g., JPEG) provides for superior performance. Determining whether to use a lossless or a lossy compression scheme depends on the application for which the neural network is to be used. For prediction tasks, a value range is known and therefore low precision suffices. As a result, even very lossy compression schemes can be applied. For training the neural network, either a lossless or a weak lossy compression scheme should be used. The specific compression method to be used can be determined from characteristics of the input data. For example, images, audio, text, etc. can be compressed differently.

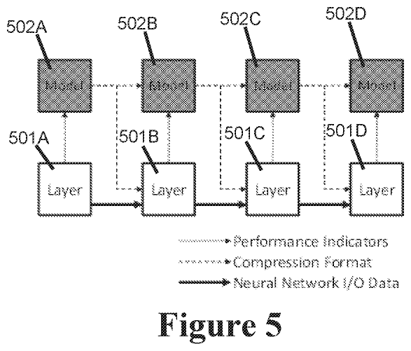

FIG. 5 illustrates modeling of execution of neural network operations during the training of a neural network according to an embodiment of the invention. FIG. 5 illustrates neural network layers 501A, 501B, 501C, and 501D and modelers 502A, 502B, 502C, and 502D. Each of the layers 501A, 501B, 501C, and 501D provides performance indicators, e.g. memory bandwidth utilization, compute utilization, execution times, and cache hit rates, to a corresponding one of the modelers 502A, 502B, 502C, and 502D. Each of the modelers 502A, 502B, 502C, and 502D profiles execution times for each of the corresponding neural network layers 501A, 501B, 501C, and 501D for the specified input and output compression formats. In addition, as the output data of one layer is the input data for the next layer, the modelers 502A, 502B, 502C, and 502D account for the compression format, i.e. the compression scheme and compression parameters, of prior layers in building execution time profiles. The execution time profiles built by the modelers 502A, 502B, 502C, and 502D, which depend, e.g., on (i) compression format of the input for a respective layer, (ii) compression format of the output for a respective layer, and (iii) compression formats of the input and output for other respective layers of the neural network, are be stored, e.g., at the main memory 302.3 of the host system 302. The compression optimizer 302.2 the utilizes such execution time profiles in determining whether a set of optimization targets is met by a certain set of compression formats in determining a compression profile, e.g. at 450 of FIG. 4.

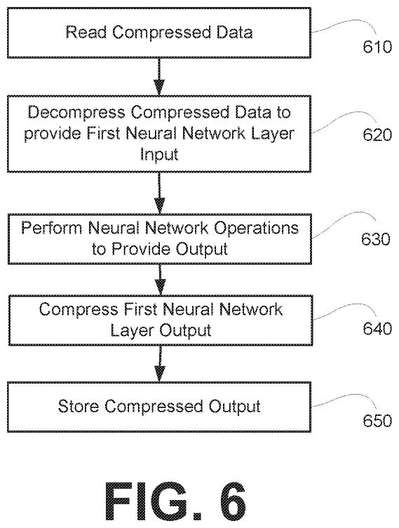

FIG. 6 illustrates a method for processing a neural network according to an embodiment of the invention. At 610, compressed input data is read from a memory. At 620, the compressed input data is decompressed to provide first neural network layer input. At 630, neural network operations associated with the first neural network layer are performed so as to provide first neural network layer output. At 640, the first neural network layer output is compressed. At 650, the compressed first neural network layer output is stored at the memory. In the method illustrated in FIG. 6, the compressed input data read from a memory at 610 is compressed using a compression format determined according to the training process described in FIG. 4. Similarly, the first neural network layer output is compressed at 640 according to a compression format determined according to the training process described in FIG. 4.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. A method for processing a neural network, the method comprising:
performing a decompression step before executing operations associated with a block of layers of the neural network;
performing a compression step after executing operations associated with the block of layers of a neural network;
gathering performance indicators for the executing the operations associated with the block of layers of the neural network; and
determining whether target performance metrics have been met with a compression format used for at least one of the decompression step and the compression step.

2. The method according to claim 1, wherein the performance indicators for executing the operations associated with the block of layers of the neural network include a computation time, a memory usage, and a model accuracy.

3. The method according to claim 1, wherein the compression format includes a compression scheme and compression parameters.

4. The method according to claim 3, wherein the compression scheme is at least one of a lossless compression scheme and a lossy compression scheme.

5. The method according to claim 3, wherein the compression parameters determine a degree of compression.

6. The method according to claim 1, wherein the method is performed during training of the neural network.

7. The method according to claim 6, wherein the method is performed after a set of gradients and weights have been determined that allow the neural network to meet a precision requirement.

8. The method according to claim 1, wherein the performing the decompression step and the performing the compression step are carried out by a compute device including a processor, a cache, and a main memory.

9. The method according to claim 8, wherein the processor is one of a CPU, a GPU, an FPGA, a vector processor, and an SIMD unit of a CPU or GPU.

10. The method according to claim 1, wherein the gathering the performance indicators and the modifying the compression format is carried out by a controller.

11. The method according to claim 1, further comprising if the target performance metrics have not been met with the compression format used for at least one of the decompression step and the compression step, modifying the compression format to meet the target performance metrics.

12. A system for processing a neural network, the system comprising:
a plurality of compute devices, each compute device including a processor, a cache, and a main memory, each of the plurality of compute devices being configured to:
read compressed input data from its main memory,
decompress the compressed input data,
perform, using the decompressed input data, neural network operations associated with a block of layers of the neural network so as to provide output data,
compress the output data,
store the compressed output data at its main memory, and
record performance indicators for the executing the operations associated with the block of layers of the neural network and report the recorded performance indicators to a controller; and
the controller, the controller including a processor and a main memory, the main memory having stored thereon computer executable instructions for:
receiving the reported performance indicators,
evaluating the reported performance indicators, and
determining whether target performance metrics have been met with a compression format used for at least one of the decompression step and the compression step.

13. The system according to claim 12, wherein the computer executable instructions stored at the main memory of the controller further include computer executable instructions for determining, if the target performance metrics have not been met with the compression format used for at least one of the decompression step and the compression step, a modified compression format to be used by the plurality of compute devices for respective decompression and compression in order to meet the target performance metrics.
